(19) United States
(12) Patent Application Publication
(10) Pub. No.: US 2024/0183604 A1
(43) Pub. Date: Jun. 6, 2024

(54) Scalable Thermalization of Wiring and Attenuation of Signals for Quantum Devices within Quantum Computing Systems

(71) Applicant: Google LLC, Mountain View, CA (US)

(72) Inventors: Bob Benjamin Buckley, Goleta, CA (US); Mike Hamilton, Mountain View, CA (US)

(21) Appl. No.: 18/073,224

(22) Filed: Dec. 1, 2022

(51) Int. Cl. F25D 19/00; F17C 13/00; F25D 19/04; G06N 10/40

(52) U.S. Cl. CPC F25D 19/006; F17C 13/007; F25D 19/04; G06N 10/40; F17C 2223/0161; F17C 2270/0527

(57) ABSTRACT

The disclosure is directed to a quantum processor system. The system includes a first cryogenic chamber, a signal reflector element positioned within the first chamber, a second cryogenic chamber, and a quantum device positioned in the second chamber. The signal reflector element is configured to split an input signal into a first signal component and a second signal component. The system further includes a first signal line and a second signal line. The first signal line is configured to provide the input signal from an external environment to the signal reflector element and to provide the reflected first signal component from the signal reflector element to the external environment. The second signal line is configured to provide the transmitted second signal component from the signal reflector element to the quantum device. The signal reflector element electrically couples the first signal line to the second signal line.

### FIELD

The present disclosure relates generally to quantum computing and information processing systems, and more particularly to thermalizing the control wiring for quantum devices (e.g., qubits) within quantum computing and information processing systems.

### BACKGROUND

Quantum computing is a computing method that takes advantage of quantum effects, such as superposition of basis states and entanglement to perform certain computations more efficiently than a classical digital computer. In contrast to a digital computer, which stores and manipulates information in the form of bits, e.g., a “1” or “0,” quantum computing systems can manipulate information using quantum bits (“qubits”). A qubit can refer to a quantum device that enables the superposition of multiple states, e.g., data in both the “0” and “1” state, and/or to the superposition of data, itself, in the multiple states. In accordance with conventional terminology, the superposition of a “0” and “1” state in a quantum system may be represented, e.g., as a |0 [symbol] +b|1 [symbol] The “0” and “1” states of a digital computer are analogous to the |0 [symbol] and |1 [symbol] basis states, respectively of a qubit.

### SUMMARY

Aspects and advantages of embodiments of the present disclosure will be set forth in part in the following description, or can be learned from the description, or can be learned through practice of the embodiments.

One example aspect of the present disclosure is directed to a quantum processor system (e.g., a quantum computing system and/or a quantum information processing system). The system may include a first cryogenic chamber, a signal reflector element positioned within the first cryogenic chamber, a second cryogenic chamber, and a quantum device positioned in the second chamber. The signal reflector element is configured to split an input signal into a first signal component and a second signal component via a partial reflection of the input signal. The partial reflection of the input signal causes the first signal component of the input signal to be reflected by the signal reflector element and the second signal component of the input signal to be transmitted by the signal reflector element. The system further includes a first signal line and a second signal line. The first signal line is configured to provide the input signal from an external environment to the signal reflector element. The first signal line is further configured to provide the reflected first signal component from the signal reflector element to the external environment. The external environment is external to each of the first cryogenic chamber and the second cryogenic chamber. The second signal line is configured to provide the transmitted second signal component from the signal reflector element to the quantum device positioned within the second cryogenic chamber. The signal reflector element electrically couples the first signal line to the second signal line such that the second signal component transmitted by the signal reflector element is transmitted to the second signal line via the signal reflector element.

Other aspects of the present disclosure are directed to various systems, methods, apparatuses, non-transitory computer-readable media, computer-readable instructions, and computing devices.

These and other features, aspects, and advantages of various embodiments of the present disclosure will become better understood with reference to the following description and appended claims. The accompanying drawings, which are incorporated in and constitute a part of this specification, illustrate example embodiments of the present disclosure and, together with the description, explain the related principles.

### BRIEF DESCRIPTION OF THE DRAWINGS

Detailed discussion of embodiments directed to one of ordinary skill in the art is set forth in the specification, which refers to the appended figures, in which:

FIG. 1A provides a schematic view of a conventional multi-stage cryogenic system and a conventional architecture typically employed to thermalize the signal lines and attenuate signals in a quantum computing system;

FIG. 1B depicts an example quantum computing system according to example embodiments of the present disclosure; and

FIGS. 2-6 provide schematics view of various enhanced multi-stage cryogenic systems and various enhanced architectures that are employable to thermalize the signal lines and attenuate signals in a quantum computing system.

### DETAILED DESCRIPTION

Example aspects of the present disclosure are directed to methods, architectures, and hardware configurations that enable thermalization of the control wiring for quantum devices (e.g., qubits, qubit couplers, and/or quantum gates) of a quantum computing and/or quantum information processing system. The embodiments enable the thermalization of the control wiring as the number of quantum devices scales to large numbers (e.g., the embodiments enable scaling such systems to at least millions of quantum devices cooled via a single cryogenic system). Conventional thermalization of the control wiring typically involves attenuating the control signals (via absorption of a significant portion of the signal) in an “intermediate” stage of the cryogenic system that maintains the coherence of the quantum devices. Such signal absorption is typically accomplished via resistive elements with the cryogenic system's intermediate stage. However, absorbing signals in the cryogenic system's intermediate stage generates a significant amount of heat. In addition, due to blackbody radiation, these absorbers radiate electromagnetic blackbody radiation with high emissivity into the cryogenic system's final stage, which houses the quantum devices. In such conventional absorption-based architectures, as the number of quantum devices scales, so too does the amount of heat load on the cryogenic system, and the amount of heat radiated to the quantum devices, resulting in loss of coherence.

Rather than absorbing signals in the cryogenic system's intermediate stage as conventional systems do, the various embodiments position “reflective” elements within the intermediate stage. Such reflective elements may not be ideal reflectors, but are rather “partial reflectors,” such that a portion of the signal is transmitted through the reflective elements. Such partial-reflective elements may act as a signal “splitter,” where a significant portion of the signal is reflected to a “heat-sink” element (e.g., positioned outside of the cryogenic system), while the “un-reflected” portion of the control signal is provided to the quantum devices within the cryogenic system's final stage. Via the partial reflection of the control signal, signal attenuation (and at least a partial signal thermalization) has been achieved such that excess heat is not radiated to the quantum devices due to the lower blackbody emissivity of the filter, and thus coherence may be maintained by the cryogenic system. If needed, the attenuated signal (e.g., the un-reflected portion of the control signal) may be further thermalized in the cryogenic system's final stage. Due to the significant reflective-attenuation (rather than absorption-based attenuation) of the control signal in the intermediate stage, such further thermalization in final stage may not generate amounts of heat significant enough to induce decoherence in the quantum devices. Such “signal splitting” (or partial signal reflection). As discussed throughout, the reflective elements may be achieved via various architectures, depending on the control signal's frequency, the control signal's amplitude, the amount of reflection or transmission required, the number of quantum devices contained in the final stage, or other various factors.

In various embodiments, a cryogenic system (of a quantum computing system) may include at least three stages: an initial stage, one or more intermediate stages, and a final stage housing the quantum devices. The initial stage may be a room temperature (RT) stage that is kept at approximately 300 kelvins. Thus, the initial stage may be referred to as the RT stage. At least one of the one or more intermediate stages may house one or more reflective (e.g., partially reflective) elements that perform the non-absorbative (e.g., reflective) signal attenuation. These one or more intermediate stages that house the reflective elements may be kept at a temperature of about 3 kelvins. Thus, these one or more intermediate stages that house the reflective elements may be collectively referred to as a “cold” or “3K” stage. The final stage that houses the quantum devices may be kept at a temperature on the order of millikelvins (e.g., 20 millikelvins), and thus the final stage may be referred to as a “ultra-cold” or “millikelvin” stage.

A control signal may be referred to as simply a signal. In some embodiments, a control signal may be a direct current (DC) signal. In other embodiments, a control signal may be an alternating current (AC) signal, e.g., a microwave signal. A control signal (e.g., destined for one or more quantum devices within the ultra-cold stage) may originate (or at least pass through) the RT stage. During its transmission along a control line and prior to reaching the ultra-code stage, the signal may pass through the cold stage housing the one or more reflective elements. The one or more reflective elements may attenuate the signal via a partial reflection of the signal. The “reflected” portion of the signal may be reflected back to the RT stage (e.g., either along the control line that provided the signal to the reflective elements or another signal line). The “transmitted” portion of the signal may continue its transmission toward the ultra-cold stage (e.g., either along the same control line or another signal line). Because the RT stage is held at approximately 300 kelvins, the RT stage may act as a heat sink, absorbing the heat associated with the reflected signal without significant adverse consequences. In some embodiments, the signal attenuation accomplished via the reflective elements is approximately 20 decibels (dB), although this attenuation factor may vary across the embodiments. Thus, the reflected signal may carry approximately 99% of the power of the original signal back to the RT stage, while the transmitted signal may carry approximately 1% of the power of the original signal to the ultra-cold stage. Due to the strong non-absorptive attenuation (e.g., approximately 20 dB) of the signal in the cold stage, the transmitted (e.g., the non-reflected portion of the) signal and/or its control line may be effectively thermalized in the ultra-cold stage without significantly heating up the ultra-cold stage. The transmitted portion of the signal may be interchangeably referred to as the attenuated signal and/or the transmitted signal.

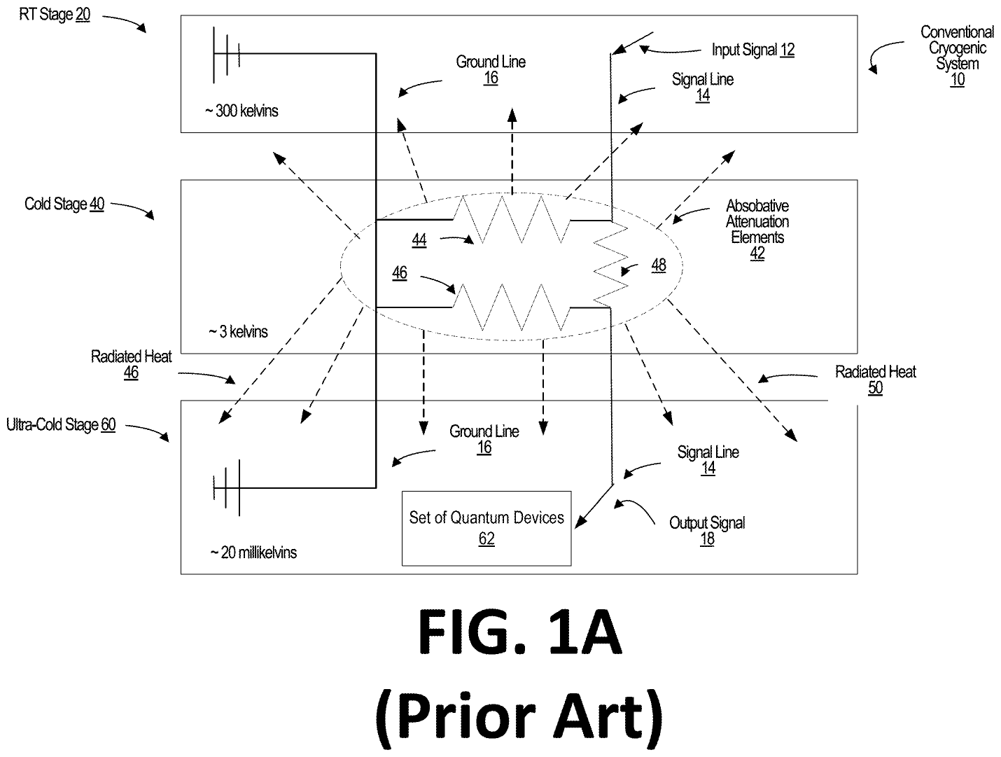

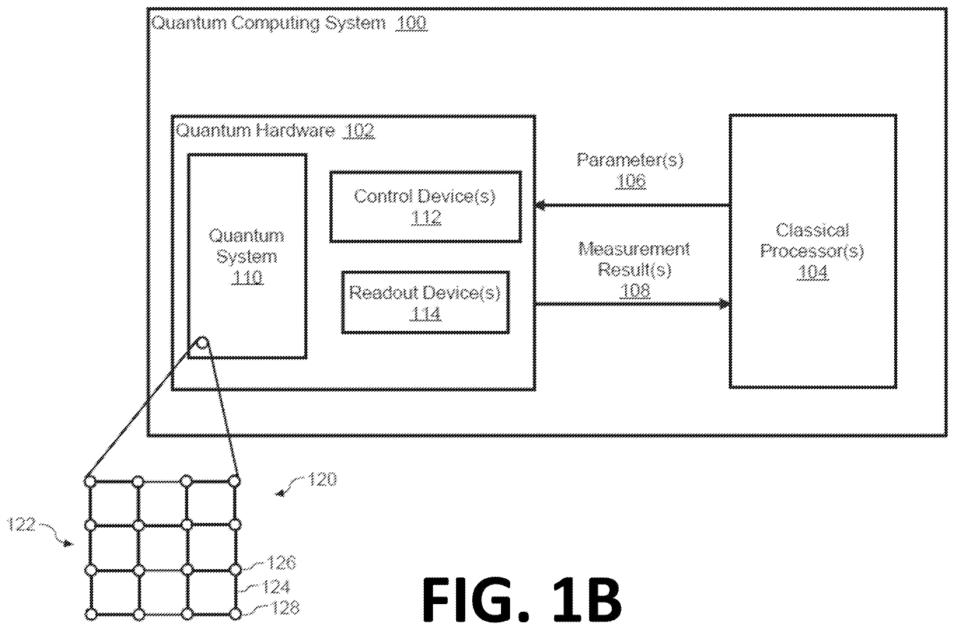

FIG. 1A provides a schematic view of a conventional multi-stage cryogenic system 10 and a conventional architecture typically employed to thermalize the signal lines and attenuate signals in a quantum computing system (QCS). The conventional cryogenic system 10 includes at least three stages: a room temperature (RT) stage 20, a cold stage 40, and an ultra-cold stage 60. As noted above, the RT stage 20 may be operated at approximately 300 kelvins and may be interchangeably referred to as an initial stage. The cold stage 40 may be operated at approximately 3 kelvins and may be interchangeably referred to as an intermediate stage. The ultra-cold stage 60 may be operated at approximately 20 millikelvins and may be interchangeably referred to as a final stage. The ultra-cold stage 60 may house a set of quantum devices 62. The set of quantum devices 62 may include a set of qubits, a set of quantum logic gates, a set of qubit couplers (e.g., employable as quantum gates), and the like.

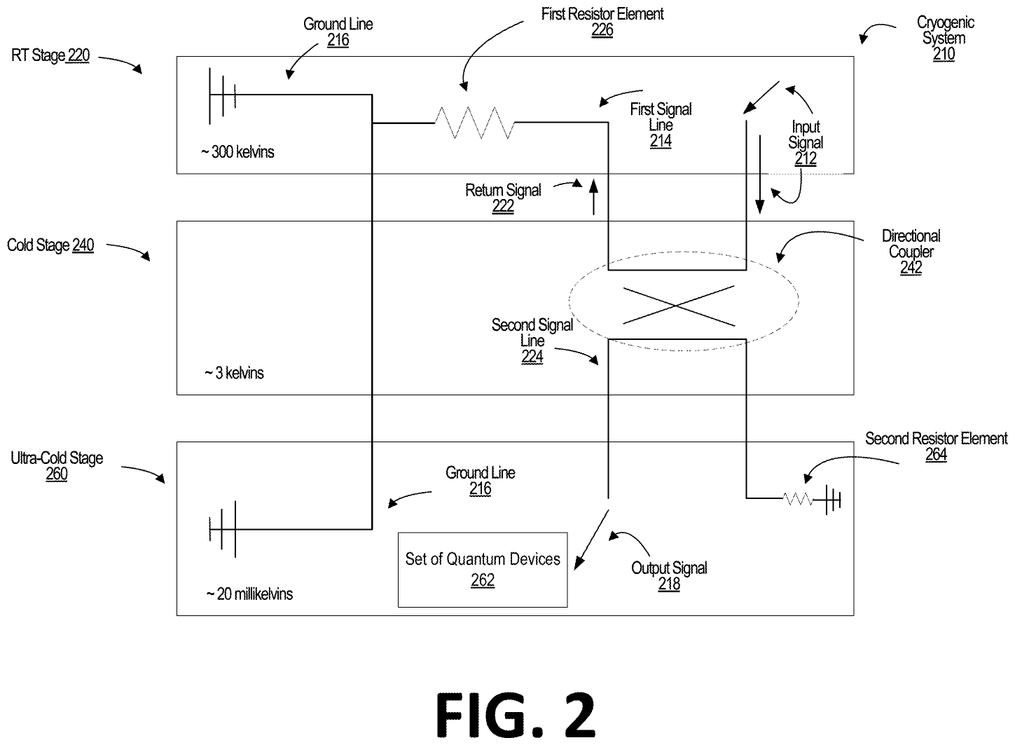

The conventional cryogenic system 10 may further include a signal line 14 (e.g., a control signal line) and a ground line 16. The signal line 14 and the ground line 16 may be electrically coupled via absorptive attenuation elements 42 housed in the cold stage 40. As shown in FIG. 2, the absorptive attenuation elements 42 may be implemented via one or more resistors. That is, signal attenuation provided by the absorptive attenuation elements 42 is accomplished via heat-generating resistive means that effectively “absorb” (and radiate) energy associated with at least a portion of the input signal 12. Thus, the absorptive attenuation elements 42 may be resistive attenuation elements. The signal line may transmit an input signal 12 towards one or more qubit devices of the set of qubit devices 62. The absorptive attenuation elements 42 in the cold stage 40 may attenuate the input signal 12 such that an attenuated output signal 18 is provided to the one or more quantum devices of the set of quantum devices. In some scenarios, to filter out much the signal noise generated in the RT stage 20, the attenuation from the input signal 12 to the output signal 14 is significant (e.g., approximately 20 dB).

The absorptive attenuation elements may include at least a first resistor 44, a second resistor 46, and a third resistor 48. The resistance of the third resistor 48 may be significantly greater than the serially combined resistance of the first resistor 44 and the second resistor 46. Thus, the third resistor 48 may effectively “re-route” a significant portion of the energy of the input signal 12 through the first and second resistors 44/46. With a significant portion of the input signal 12 re-routed through the first resistor 44, the first resistor may act to significantly attenuate the input signal 12, and absorb a significant amount of energy of the input signal 12. Thus, the first resistor 44 may act as a heat radiator and be referred to as a heat radiation resistor (e.g., Rₕₑₐₜ). The first resistor 44 may radiate the radiated heat 50 towards the ultra-cold stage 60. The second resistor 46 may serve a “bridge” back to the signal line 14 and redirect the remaining portion of the attenuated input signal 12 (e.g., the output signal 18) back towards the ultra-cold stage 60. That is, the second resistor 46 may “emit” the output signal (as well as its temperature and resulting noise) to the ultra-cold environment. Thus, the second resistor 46 may be referred to as a signal an/or heat emitting resistor (e.g., Rₑₘᵢₜ). Thus, the second resistor 45 emits 3k noise to the ultra-cold stage 60. Note that the first resistor 44 (i.e., Rₕₑₐₜ), the second resistor 46 (i.e., Rₑₘᵢₜ), and the third resistor 46 are operated at the same temperatures (e.g., ˜3 kelvins).

Resistive attenuation by the absorptive attenuation elements 42 may generate significant amounts of heat that is radiated away from the cold stage 40. Such radiated heat 45 is shown by the hashed arrows pointing away from the absorptive attenuation elements 42. As shown in FIG. 1A, at least a portion of the radiated heat 50 (e.g., via the first resistor 44) is deposited in the ultra-cold stage 60. The radiated heat 50 may warm up the ultra-cold stage 60, resulting in decoherence within the set of quantum devices 62. Decoherence in the set of quantum devices 62 may degrade the computational and information processing capabilities of the QCS. Note that as the cardinality of the set of quantum devices 62 scales, so to does the number of signals lines 14. Accordingly, as the number of quantum devices used by the QCS, the ability to control the temperature of the ultra-cold stage 60 and/or the coherence of the set of quantum devices 62 become increasingly difficult to maintain, via conventional absorptive attenuation architectures and methods.

Various embodiments disclosed herein replace the absorptive attenuation elements 42 with reflective elements that operate as a signal splitter. The signal splitter acters to provide similar attenuation levels of the input signal 12. However, in contrast to the absorptive attenuation elements 42, the attenuation provided by the reflective elements does not generate significant amounts of heat. Rather, the component of the input signal 12 that is not to be provided to the ultra-cold stage 60 is redirected to the RT stage 20, which may act as an effective heat sink that does not affect the ultra-cold stage 60. The component of the input signal 12 that is to be provided to the ultra-cold stage 60 (e.g., the output signal 18) is transmitted through the reflective elements. Due to the significant signal attenuation accomplished via splitting the signal via reflective elements (rather than absorptive attenuation elements), the signal line 14 and/or the significantly attenuated output signal 18 may be thermalized in the ultra-cold stage 60 without significantly heating up the ultra-cold stage 60 and/or affecting the coherence of the set of quantum devices 62.

It should be noted that application of the embodiments are not limited to quantum computing and quantum information processing systems. Rather, the embodiments may be employed in any application that uses a multi-stage cryogenic system, where signals originate from a warmer environment (e.g., an RT environment) and are transmitted to a colder environment (e.g., an ultra-cold environment). The embodiments may be employed any application where signals from the environment (e.g., a RT environment) need to be thermalized and/or attenuated prior to being provided to the ultra-cold environment, without significantly radiating heat to the ultra-cold environment. Note that such non-absorptive attenuation may be useful to filter out a significant portion of the signal noise generated in the RT environment, such that the filtered-out portion of the noise is not transmitted to the ultra-cold environment, where the noise would have larger consequences.

Aspects of the present disclosure provide a number of technical effects and benefits. For instance, partially reflecting rather than resistively absorbing control signals in the cryogenic system's intermediate stage enables scaling the number of quantum devices within a cryogenic system's final stage by at least on several orders of magnitude, without radiating significant amounts of heat into the final stage. As such, maintaining coherence among millions of qubits and/or logic gates may be achieved. Accordingly, scalable quantum computation and quantum information processing is achievable via the various embodiments.

FIG. 1B depicts an example quantum computing system 100. The system 100 is an example of a system of one or more classical computers and/or quantum computing devices in one or more locations, in which the systems, components, and techniques described below can be implemented. Those of ordinary skill in the art, using the disclosures provided herein, will understand that other quantum computing devices or systems can be used without deviating from the scope of the present disclosure.

The system 100 includes quantum hardware 102 in data communication with one or more classical processors 104. The classical processors 104 can be configured to execute computer-readable instructions stored in one or more memory devices to perform operations, such as any of the operations described herein. The quantum hardware 102 includes components for performing quantum computation. For example, the quantum hardware 102 includes a quantum system 110, control device(s) 112, and readout device(s) 114 (e.g., readout resonator(s)). The quantum system 110 can include one or more multi-level quantum subsystems, such as a register of qubits (e.g., qubits 120). In some implementations, the multi-level quantum subsystems can include superconducting qubits, such as flux qubits, charge qubits, transmon qubits, gmon qubits, spin-based qubits, and the like.

The type of multi-level quantum subsystems that the system 100 utilizes may vary. For example, in some cases it may be convenient to include one or more readout device(s) 114 attached to one or more superconducting qubits, e.g., transmon, flux, gmon, xmon, or other qubits. In other cases, ion traps, photonic devices or superconducting cavities (e.g., with which states may be prepared without requiring qubits) may be used. Further examples of realizations of multi-level quantum subsystems include fluxmon qubits, silicon quantum dots or phosphorus impurity qubits.

Quantum circuits may be constructed and applied to the register of qubits included in the quantum system 110 via multiple control lines that are coupled to one or more control devices 112. Example control devices 112 that operate on the register of qubits can be used to implement quantum gates or quantum circuits having a plurality of quantum gates, e.g., Pauli gates, Hadamard gates, controlled-NOT (CNOT) gates, controlled-phase gates, T gates, multi-qubit quantum gates, coupler quantum gates, etc. The one or more control devices 112 may be configured to operate on the quantum system 110 through one or more respective control parameters (e.g., one or more physical control parameters). For example, in some implementations, the multi-level quantum subsystems may be superconducting qubits and the control devices 112 may be configured to provide control pulses to control lines to generate magnetic fields to adjust the frequency of the qubits.

The quantum hardware 102 may further include readout devices 114 (e.g., readout resonators). Measurement results 108 obtained via measurement devices may be provided to the classical processors 104 for processing and analyzing. In some implementations, the quantum hardware 102 may include a quantum circuit and the control device(s) 112 and readout devices(s) 114 may implement one or more quantum logic gates that operate on the quantum system 102 through physical control parameters (e.g., microwave pulses) that are sent through wires included in the quantum hardware 102. Further examples of control devices include arbitrary waveform generators, wherein a DAC (digital to analog converter) creates the signal.

The readout device(s) 114 may be configured to perform quantum measurements on the quantum system 110 and send measurement results 108 to the classical processors 104. In addition, the quantum hardware 102 may be configured to receive data specifying physical control qubit parameter values 106 from the classical processors 104. The quantum hardware 102 may use the received physical control qubit parameter values 106 to update the action of the control device(s) 112 and readout devices(s) 114 on the quantum system 110. For example, the quantum hardware 102 may receive data specifying new values representing voltage strengths of one or more DACs included in the control devices 112 and may update the action of the DACs on the quantum system 110 accordingly. The classical processors 104 may be configured to initialize the quantum system 110 in an initial quantum state, e.g., by sending data to the quantum hardware 102 specifying an initial set of parameters 106.

In some implementations, the readout device(s) 114 can take advantage of a difference in the impedance for the |0) and | 1) states of an element of the quantum system, such as a qubit, to measure the state of the element (e.g., the qubit). For example, the resonance frequency of a readout resonator can take on different values when a qubit is in the state |0) or the state |1), due to the nonlinearity of the qubit. Therefore, a microwave pulse reflected from the readout device 114 carries an amplitude and phase shift that depend on the qubit state. In some implementations, a Purcell filter can be used in conjunction with the readout device(s) 114 to impede microwave propagation at the qubit frequency.

In some embodiments, the quantum system 110 can include a plurality of qubits 120 arranged, for instance, in a two-dimensional grid 122. For clarity, the two-dimensional grid 122 depicted in FIG. 1B includes 4×4 qubits, however in some implementations the system 110 may include a smaller or a larger number of qubits. In some embodiments, the multiple qubits 120 can interact with each other through multiple qubit couplers, e.g., qubit coupler 124. The qubit couplers can define nearest neighbor interactions between the multiple qubits 120. In some implementations, the strengths of the multiple qubit couplers are tunable parameters. In some cases, the multiple qubit couplers included in the quantum computing system 100 may be couplers with a fixed coupling strength.

In some implementations, the multiple qubits 120 may include data qubits, such as qubit 126 and measurement qubits, such as qubit t,. A data qubit is a qubit that participates in a computation being performed by the system 100. A measurement qubit is a qubit that may be used to determine an outcome of a computation performed by the data qubit. That is, during a computation an unknown state of the data qubit is transferred to the measurement qubit using a suitable physical operation and measured via a suitable measurement operation performed on the measurement qubit.

In some implementations, each qubit in the multiple qubits 120 can be operated using respective operating frequencies, such as an idling frequency and/or an interaction frequency and/or readout frequency and/or reset frequency. The operating frequencies can vary from qubit to qubit. For instance, each qubit may idle at a different operating frequency. The operating frequencies for the qubits 120 can be chosen before a computation is performed.

FIG. 1B depicts one example quantum computing system that can be used to implement the methods and operations according to example aspects of the present disclosure. Other quantum computing systems can be used without deviating from the scope of the present disclosure.

FIG. 2 provides a schematic view of an enhanced multi-stage cryogenic system 210 and an enhanced architecture that is employable to thermalize the signal lines and attenuate signals in a quantum computing system (QCS). The embodiment shown in FIG. 2 may be an alternating current (AC) embodiment because it is directed towards an AC (e.g., a radiofrequency (RF)) input signal 212. The enhanced cryogenic system 210 includes at least three stages: a room temperature (RT) stage 220, a cold stage 240, and an ultra-cold stage 260. The RT stage 220 may be operated at approximately 300 kelvins and may be interchangeably referred to as an initial stage of the cryogenic system 210. The cold stage 240 may be operated at approximately 3 kelvins and may be interchangeably referred to as an intermediate stage of the cryogenic system 210. The ultra-cold stage 260 may be operated at approximately 220 millikelvins and may be interchangeably referred to as a final stage of the cryogenic system 210. The ultra-cold stage 260 may house a set of quantum devices 262. The set of quantum devices 262 may include a set of qubits, a set of quantum logic gates, a set of qubit couplers (e.g., employable as quantum gates), and the like. For instance, the set of quantum devices may include the multiple qubits 120, the two-dimensional grid 122, and/or the qubit coupler 124 of FIG. 1B.

The enhanced cryogenic system 210 may further include a first signal line 214 (e.g., a control signal line), a second signal line 224, and a ground line 216. As shown in FIG. 2, the first signal line 214 may run from the RT stage 220, into the cold stage 240, and return back to the RT stage 220. As also shown in FIG. 2, the second signal line 224 may run from the ultra-cold stage 260, into the cold stage 240, and return to the ultra-cold stage 260. The first signal line 214 and the ground line 216 may be electrically coupled (in the RT stage 220) via a first resistor element 226 positioned in the RT stage 220. The second signal line 224 may be electrically coupled to ground (e.g., which may be but need not be the ground line 216) via a second resistor element 264 positioned in the ultra-cold stage 260. The first signal line 214 and the second signal line 224 may be electrically coupled in the cold stage 240 via a directional coupler 242. The ground line 216 and the second resistor element 264 may be electrically coupled to an electrical ground.

The directional coupler 242 may serve as a signal reflector element in the cold stage 240, as well as to electrically couple the first signal line 214 with the second signal line 224. That is, the directional coupler 242 may reflect a portion of the input signal 212 (e.g., the return signal 222) and transmit the remaining portion of the input signal (e.g., output signal 218) to the second signal line 224. The directional coupler 242 may serve as a signal “splitter” element that splits the input signal 212 into a return signal 222 and an output signal 218, via a partial reflection of the input signal 212. The return signal 222 may be referred to as a reflected signal component (e.g., a first signal component) and the output signal 218 may be referred to as a transmitted signal component (e.g., a second signal component). Thus, via the partial reflection, the directional coupler 242 (e.g., a signal reflector element) is configured to split the input signal 212 into a reflected signal component (e.g., that is reflected by the signal reflector element) and a transmitted signal component (e.g., that is transmitted by the signal reflector element).

Via the splitting of the input signal 212 into the return signal 222 and the output signal 218, the directional coupler 242 may serve to attenuate the input signal 212. In some embodiments, the directional coupler 242 attenuates the input signal 212 by approximately 20 dBs. The attenuation accomplished via the directional coupler 242 is a “reflective” attenuation, rather than an absorptive attenuation, as shown in FIG. 1A. Accordingly, the signal attenuation accomplished in the cold stage 240 does not generate the heat in the cold stage 240, in contrast to the heat generation in the cold stage 40 of FIG. 1A. The return signal 222 is returned to the RT stage 220 via the first signal line 214, and the output signal 218 is provided to the ultra-cold stage 260 and one or more quantum devices of the set of quantum devices 262 via the second signal line 224.

The first resistor element 226 may act as a heat absorber and be referred to as a heat absorber resistor (e.g., Rₕₑₐₜ). In some embodiments, the resistance of the first resistor element 226 may be approximately 50 ohms. The second resistor element 264 may “absorb” and “emit” at ultra-cold temperatures. Thus, the second resistor element 264 may be referred to as a cold blackbody emitter & absorber (e.g., Rₑₘᵢₜ). The second resistor element 264 may serve to thermalize the output signal 218 and/or the portion of the second signal line 224 that is in the ultra-cold stage 260. Because the output signal 218 has been significantly attenuated, the amount of heat deposited in the ultra-cold stage 260 has been significantly attenuated. In some embodiments, the resistance of the second resistor element 264 may be approximately 50 ohms.

In reference to FIG. 2, the cold stage 240 may include a first cryogenic chamber and the ultra-cold stage 260 may include a second cryogenic chamber. Thus, one or more quantum devices (e.g., a qubit, a qubit coupler, a quantum logic gate, or the like) of the set of quantum devices 262 may be positioned within the second cryogenic chamber. In at least one embodiment, the second cryogenic chamber may be nested in the first cryogenic chamber. The RT stage 220 may, or may not, include a third cryogenic chamber. That is, the RT stage 220 may be outside any cryogenic chamber. The RT stage may include an external environment that is external to each of the first cryogenic chamber and the second cryogenic chamber. A signal reflector element (e.g., the directional coupler 242) is positioned within the first cryogenic chamber. The signal reflector element is configured to split the input signal 212 into a first signal component (e.g., the return signal 222) and a second signal component (e.g., the output signal 218) via a partial reflection of the input signal 212. The partial reflection of the input signal 212 causes the first signal component of the input signal 212 to be reflected by the signal reflector element and the second signal component of the input signal 212 to be transmitted by the signal reflector element. The partial reflection of the input signal 212 causes an attenuation of the input signal 212 such that the second signal component (e.g., the output signal 218) is an attenuated signal of the input signal 212. The attenuation of the input signal 212 may be approximately a 20 decibel (dB) attenuation. When the signal reflector element is a directional coupler, the input signal 212 may be an alternating current (AC) signal. The input signal 212 may be a radiofrequency (RF) signal.

As shown in FIG. 2, the input signal 212 may originate in the external environment. The first signal line 214 is further configured to provide the reflected first signal component from the signal reflector element to the external environment. The second signal line 224 is configured to provide the transmitted second signal component from the signal reflector element to the quantum device positioned within the second cryogenic chamber. The signal reflector element electrically couples the input signal 212 to the second signal line such that the second signal component transmitted by the signal reflector element is transmitted to the second signal line via the signal reflector element.

The ground line 216 may pass through the external environment, the first cryogenic chamber, and the second cryogenic chamber. As shown in FIG. 2, the ground line 216 may be electrically coupled to an electrical ground. A resistor element (e.g., the first resistor element 226) may be positioned in the external environment. The first resistor element 226 couples the first signal line 214 to the electrical ground such that heat associated with energy of the first signal component (e.g., the return signal 222) is dissipated to the external environment. Another resistor element (e.g., the second resistor element 264) may be positioned in the second cryogenic chamber. The second resistor element 264 couples the second signal line 224 to the electrical ground such that the second signal component (e.g., the output signal 218) is at least partially thermalized in the second cryogenic chamber.

The input signal line 212 may include a first portion that transmits the input signal 212 from the external environment to the signal reflector element. The first signal line 214 may include a second portion that transmits the first signal component (e.g., the return signal 222) from the signal reflector element to the external environment. The first portion and the second portion of the first signal line 214 may be disjoint portions such that the input signal 212 and the first signal component are transmitted by disjoint portions of the first signal line 214.

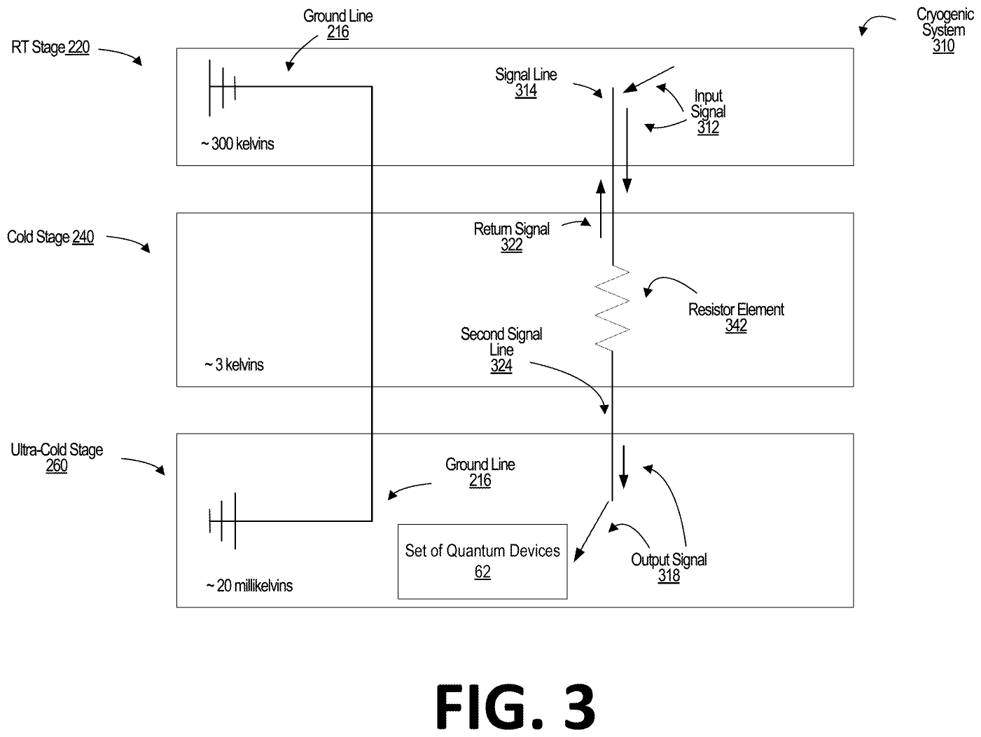

FIG. 3 provides a schematic view of another enhanced multi-stage cryogenic system 310 and an enhanced architecture that is employable to thermalize the signal lines and attenuate signals in a quantum computing system (QCS). The embodiment shown in FIG. 3 may be an alternating current (AC) embodiment because it is directed towards an AC (e.g., a radiofrequency (RF)) input signal 312. However, the embodiment shown in FIG. 3 is not so limited and may be a direct current (DC) embodiment, because it can transmit a DC input signal 312. The enhanced cryogenic system 310 includes at least three stages: the room temperature (RT) stage 220 of FIG. 2, the cold stage 40 of FIG. 2, and the ultra-cold stage 260 of FIG. 2. As discussed in conjunction with FIG. 2, the RT stage 220 may be operated at approximately 300 kelvins and may be interchangeably referred to as an initial stage of the cryogenic system 210. The cold stage 240 may be operated at approximately 3 kelvins and may be interchangeably referred to as an intermediate stage of the cryogenic system 210. The ultra-cold stage 260 may be operated at approximately 220 millikelvins and may be interchangeably referred to as a final stage of the cryogenic system 210. The ultra-cold stage 260 may house the set of quantum devices 262 of FIG. 2. The set of quantum devices 262 may include a set of qubits, a set of quantum logic gates, a set of qubit couplers (e.g., employable as quantum gates), and the like. For instance, the set of quantum devices may include the multiple qubits 120, the two-dimensional grid 122, and/or the qubit coupler 124 of FIG. 1B.

The enhanced cryogenic system 310 may further include a first signal line 314 (e.g., a control signal line), a second signal line 324, and the ground line 216 of FIG. 2. As shown in FIG. 3, the first signal line 314 may run between the RT stage 220 and the cold stage 240. As also shown in FIG. 3, the second signal line 324 may run between the ultra-cold stage 260 and the cold stage 240. The first signal line 314 and the second signal line 324 may be electrically coupled in the cold stage 240 via a resistor element 342.

The resistance of the resistor element 342 may be large enough that the resistor element 342 may serve as a signal reflector element in the cold stage 240, as well as to electrically couple the first signal line 314 with the second signal line 324. That is, the resistor element 342 may reflect a portion of the input signal 312 (e.g., the return signal 322) and transmit the remaining portion of the input signal (e.g., output signal 318) to the second signal line 324. The resistor element 342 may serve as a signal “splitter” element that splits the input signal 312 into a return signal 322 and an output signal 318, via a partial reflection of the input signal 312. The return signal 322 may be referred to as a reflected signal component (e.g., a first signal component) and the output signal 318 may be referred to as a transmitted signal component (e.g., a second signal component). Thus, via the partial reflection, the resistor element 342 (e.g., a signal reflector element) is configured to split the input signal 312 into a reflected signal component (e.g., that is reflected by the signal reflector element) and a transmitted signal component (e.g., that is transmitted by the signal reflector element).

Via the splitting of the input signal 312 into the return signal 322 and the output signal 318, the resistor element 342 may serve to attenuate the input signal 312. In some embodiments, the resistor element 342 attenuates the input signal 312 by approximately 20 dBs. The attenuation accomplished via the resistor element 342 is a “reflective” attenuation, rather than an absorptive attenuation, as shown in FIG. 1A. As noted above, the resistance of the resistor element 342 may be large enough that the resistor element 342 (e.g., >>50 Ohms) may serve as a signal reflector element in the cold stage 240. Selecting the resistance may be based on the amplitude of the current and/or voltage of the input signal 312 and/or the value of desired reflective attenuation, e.g., 20 dBs. Reflective attenuation, rather than absorbative attenuation may be achieved by selecting the resistance of the resistor element 342 to be sufficiently larger than the absorbative attenuation elements 42 of FIG. 1A. Accordingly, the signal attenuation accomplished in the cold stage 240 does not generate the heat in the cold stage 240, in contrast to the heat generation in the cold stage 40 of FIG. 1A. The return signal 322 is returned to the RT stage 220 via the first signal line 314, and the output signal 318 is provided to the ultra-cold stage 260 and one or more quantum devices of the set of quantum devices 262 via the second signal line 324. In embodiments where the input signal is an alternating current (AC) signal, the resistor element 342 may be replaced and/or augmented with a circulator element. The employment of a circulator element may help to mitigate some unwanted aspects of the reflections of the input signal 312.

In reference to FIG. 3, the cold stage 240 may include a first cryogenic chamber and the ultra-cold stage 260 may include a second cryogenic chamber. Thus, one or more quantum devices (e.g., a qubit, a qubit coupler, a quantum logic gate, or the like) of the set of quantum devices 262 may be positioned within the second cryogenic chamber. In at least one embodiment, the second cryogenic chamber may be nested in the first cryogenic chamber. The RT stage 220 may, or may not, include a third cryogenic chamber. That is, the RT stage 220 may be outside any cryogenic chamber. The RT stage may include an external environment that is external to each of the first cryogenic chamber and the second cryogenic chamber. A signal reflector element (e.g., the resistor element 342) is positioned within the first cryogenic chamber. The signal reflector element is configured to split the input signal 312 into a first signal component (e.g., the return signal 322) and a second signal component (e.g., the output signal 318) via a partial reflection of the input signal 312. The partial reflection of the input signal 312 causes the first signal component of the input signal 312 to be reflected by the signal reflector element and the second signal component of the input signal 312 to be transmitted by the signal reflector element. The partial reflection of the input signal 312 causes an attenuation of the input signal 312 such that the second signal component (e.g., the output signal 318) is an attenuated signal of the input signal 212. The attenuation of the input signal 312 may be approximately a 20 decibel (dB) attenuation. When the signal reflector element is a circulator element, the input signal 212 may be an alternating current (AC) signal. When the signal reflector element is the resistor element 342, the input signal 312 may be a direct current (DC) signal.

The first signal line 314 may be configured to provide the input signal 312 from an external environment (e.g., the RT stage 220) to the signal reflector element. As shown in FIG. 3, the input signal 312 may originate in the external environment. The first signal line 314 is further configured to provide the reflected first signal component from the signal reflector element to the external environment. The second signal line 324 is configured to provide the transmitted second signal component from the signal reflector element to the quantum device positioned within the second cryogenic chamber. The signal reflector element (e.g., the resistor element 342) electrically couples the first signal line 314 to the second signal line 324 such that the second signal component transmitted by the signal reflector element is transmitted to the second signal line via the signal reflector element.

The ground line 216 may pass through the external environment, the first cryogenic chamber, and the second cryogenic chamber. As shown in FIG. 3, the ground line 216 may be electrically coupled to an electrical ground. The first signal line 314 may include a common portion that is configured to transmit the input signal 312 from the external environment (e.g., the RT stage 220) to the signal reflector element (e.g., the resistor element 342). The common portion of the first signal line 314 may be further configured to transmit the first signal component (e.g., the return signal 322) from the signal reflector element to the external environment such that the input signal 312 and the first signal component are both transmitted by the common portion of the first signal line 314.

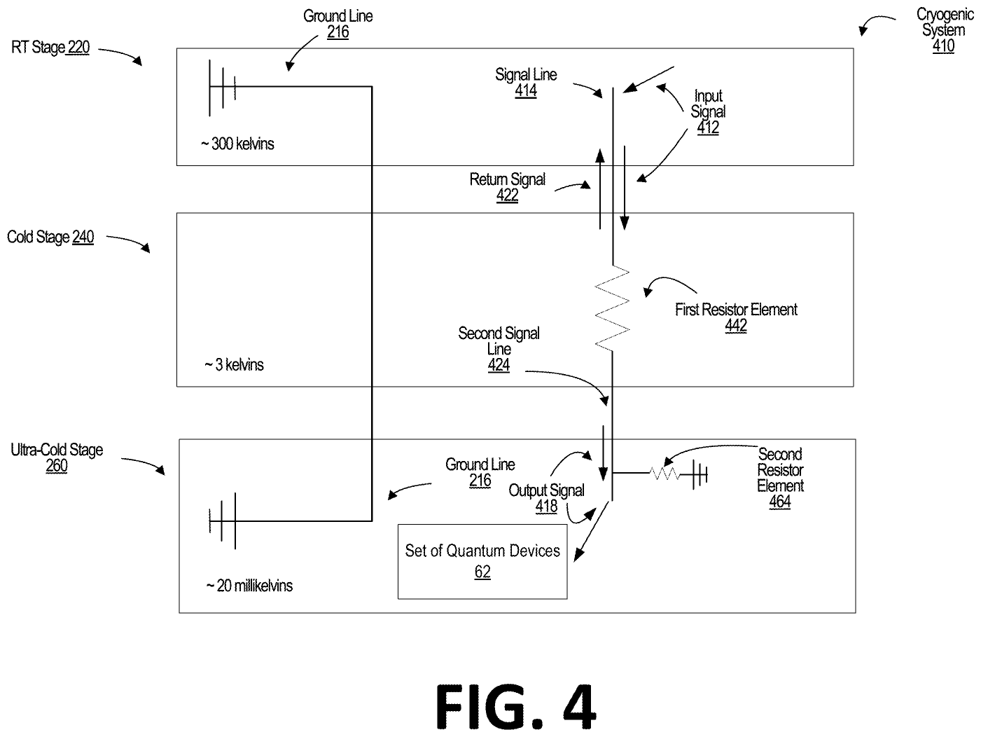

FIG. 4 provides a schematic view of still another enhanced multi-stage cryogenic system 410 and an enhanced architecture that is employable to thermalize the signal lines and attenuate signals in a quantum computing system (QCS). The enhanced cryogenic system 410 of FIG. 4 may be similar to the enhanced cryogenic system 310 of FIG. 3, with the includes of a second resistor element 464 element, positioned in the ultra-cold stage 260, tied to an electrical ground. The inclusion of the second resistor element 464 in the ultra-cold stage 260 may provide and/or enable similar functionalities to the inclusion of the second resistor element 264 of the enhanced cryogenic system 210 of FIG. 2.

Similar to enhanced cryogenic system 310 of FIG. 3, the enhanced cryogenic system 410 shown in FIG. 4 may be an alternating current (AC) embodiment because it is directed towards an AC (e.g., a radiofrequency (RF)) input signal 412. However, the embodiment shown in FIG. 4 is not so limited and may be a direct current (DC) embodiment, because it alternatively may be directed towards a DC input signal 412. The enhanced cryogenic system 410 includes at least three stages: the room temperature (RT) stage 220 of FIG. 2, the cold stage 40 of FIG. 2, and the ultra-cold stage 260 of FIG. 2. As discussed in conjunction with FIG. 2, the RT stage 220 may be operated at approximately 300 kelvins and may be interchangeably referred to as an initial stage of the cryogenic system 210. The cold stage 240 may be operated at approximately 3 kelvins and may be interchangeably referred to as an intermediate stage of the cryogenic system 210. The ultra-cold stage 260 may be operated at approximately 220 millikelvins and may be interchangeably referred to as a final stage of the cryogenic system 210. The ultra-cold stage 260 may house the set of quantum devices 262 of FIG. 2. The set of quantum devices 262 may include a set of qubits, a set of quantum logic gates, a set of qubit couplers (e.g., employable as quantum gates), and the like. For instance, the set of quantum devices may include the multiple qubits 120, the two-dimensional grid 122, and/or the qubit coupler 124 of FIG. 1B.

The enhanced cryogenic system 410 may further include a first signal line 414 (e.g., a control signal line), a second signal line 424, and the ground line 216 of FIG. 2. As shown in FIG. 4, the first signal line 414 may run between the RT stage 220 and the cold stage 240. As also shown in FIG. 4, the second signal line 424 may run between the ultra-cold stage 260 and the cold stage 240. The first signal line 414 and the second signal line 324 may be electrically coupled in the cold stage 240 via a first resistor element 442.

The resistance of the first resistor element 442 may be large enough that the first resistor element 442 may serve as a signal reflector element in the cold stage 240, as well as to electrically couple the first signal line 414 with the second signal line 424. That is, the first resistor element 442 may reflect a portion of the input signal 412 (e.g., the return signal 422) and transmit the remaining portion of the input signal (e.g., output signal 418) to the second signal line 424. The first resistor element 442 may serve as a signal “splitter” element that splits the input signal 412 into a return signal 422 and an output signal 418, via a partial reflection of the input signal 412. The return signal 422 may be referred to as a reflected signal component (e.g., a first signal component) and the output signal 418 may be referred to as a transmitted signal component (e.g., a second signal component). Thus, via the partial reflection, the first resistor element 442 (e.g., a signal reflector element) is configured to split the input signal 412 into a reflected signal component (e.g., that is reflected by the signal reflector element) and a transmitted signal component (e.g., that is transmitted by the signal reflector element).

Via the splitting of the input signal 412 into the return signal 422 and the output signal 418, the first resistor element 442 may serve to attenuate the input signal 412. In some embodiments, the first resistor element 442 attenuates the input signal 412 by approximately 20 dBs. The attenuation accomplished via the resistor element 442 is a “reflective” attenuation, rather than an absorptive attenuation, as shown in FIG. 1A. Accordingly, the signal attenuation accomplished in the cold stage 240 does not generate the heat in the cold stage 240, in contrast to the heat generation in the cold stage 40 of FIG. 1A. The return signal 422 is returned to the RT stage 220 via the first signal line 414, and the output signal 418 is provided to the ultra-cold stage 460 and one or more quantum devices of the set of quantum devices 262 via the second signal line 424. In embodiments where the input signal is an alternating current (AC) signal, the first resistor element 442 may be replaced with a circulator element.

The second resistor element 464 may “emit” the output signal 418 to the ultra-cold environment. Thus, the second resistor element 464 may be referred to as a signal an/or heat emitting resistor (e.g., Rₑₘᵢₜ). The second resistor element 464 may serve to thermalize the output signal 418 and/or the portion of the second signal line 424 that is in the ultra-cold stage 260. Because the output signal 418 has been significantly attenuated, the amount of heat deposited in the ultra-cold stage 260 has been significantly attenuated. In some embodiments, the resistance of the second resistor element 264 may be approximately 50 ohms. For AC embodiments, the “short-to-ground” accomplished via the second resistor element 464 may serve to significantly reduce reflections of the output signal 418 along the second signal line 424.

In reference to FIG. 4, the cold stage 240 may include a first cryogenic chamber and the ultra-cold stage 260 may include a second cryogenic chamber. Thus, one or more quantum devices (e.g., a qubit, a qubit coupler, a quantum logic gate, or the like) of the set of quantum devices 262 may be positioned within the second cryogenic chamber. In at least one embodiment, the second cryogenic chamber may be nested in the first cryogenic chamber. The RT stage 220 may, or may not, include a third cryogenic chamber. That is, the RT stage 220 may be outside any cryogenic chamber. The RT stage may include an external environment that is external to each of the first cryogenic chamber and the second cryogenic chamber. A signal reflector element (e.g., the first resistor element 442) is positioned within the first cryogenic chamber. The signal reflector element is configured to split the input signal 412 into a first signal component (e.g., the return signal 422) and a second signal component (e.g., the output signal 418) via a partial reflection of the input signal 412. The partial reflection of the input signal 412 causes the first signal component of the input signal 412 to be reflected by the signal reflector element and the second signal component of the input signal 412 to be transmitted by the signal reflector element. The partial reflection of the input signal 412 causes an attenuation of the input signal 412 such that the second signal component (e.g., the output signal 418) is an attenuated signal of the input signal 412. The attenuation of the input signal 412 may be approximately a 20 decibel (dB) attenuation. When the signal reflector element is a circulator element, the input signal 412 may be an alternating current (AC) signal. When the signal reflector element is the first resistor element 442, the input signal 312 may be a direct current (DC) or an AC signal.

The first signal line 414 may be configured to provide the input signal 412 from an external environment (e.g., the RT stage 220) to the signal reflector element. As shown in FIG. 4, the input signal 412 may originate in the external environment. The first signal line 414 is further configured to provide the reflected first signal component from the signal reflector element to the external environment. The second signal line 424 is configured to provide the transmitted second signal component from the signal reflector element to the quantum device positioned within the second cryogenic chamber. The signal reflector element (e.g., the first resistor element 442) electrically couples the first signal line 414 to the second signal line 424 such that the second signal component transmitted by the signal reflector element is transmitted to the second signal line via the signal reflector element.

The ground line 416 may pass through the external environment, the first cryogenic chamber, and the second cryogenic chamber. As shown in FIG. 4, the ground line 216 may be electrically coupled to an electrical ground. The first signal line 414 may include a common portion that is configured to transmit the input signal 412 from the external environment (e.g., the RT stage 220) to the signal reflector element (e.g., the first resistor element 442). The common portion of the first signal line 414 may be further configured to transmit the first signal component (e.g., the return signal 422) from the signal reflector element to the external environment such that the input signal 412 and the first signal component are both transmitted by the common portion of the first signal line 414. Another resistor element (e.g., the second resistor element 464) may be positioned in the second cryogenic chamber. The second resistor element 464 couples the second signal line 424 to the electrical ground such that the second signal component (e.g., the output signal 418) is at least partially thermalized in the second cryogenic chamber.

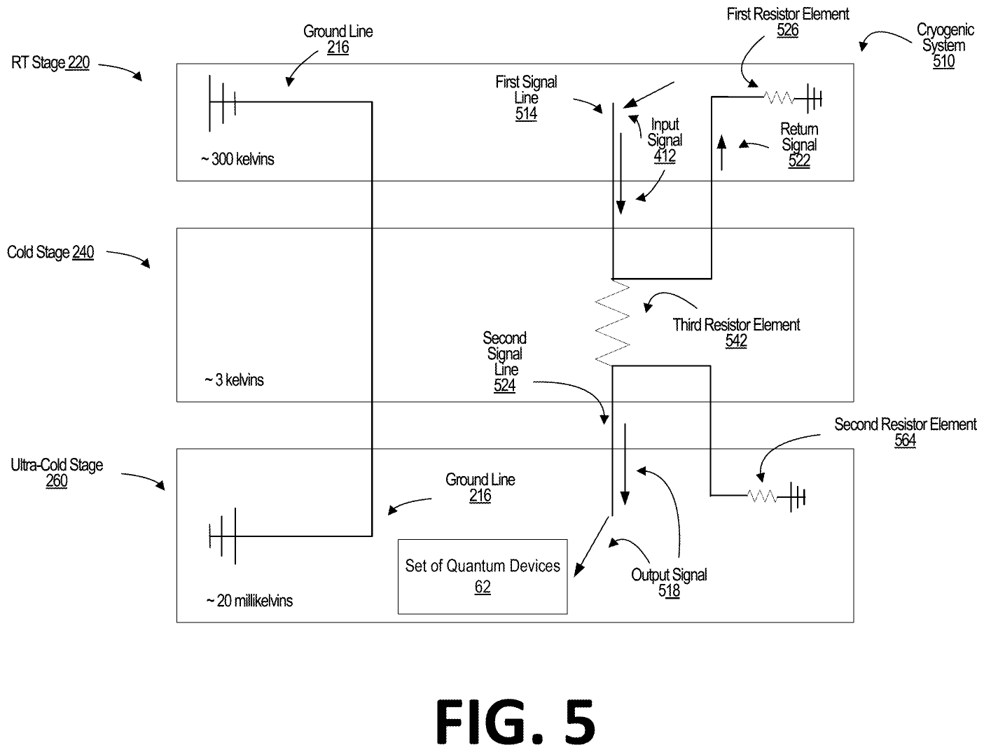

FIG. 5 provides a schematic view of still another enhanced multi-stage cryogenic system 510 and an enhanced architecture that is employable to thermalize the signal lines and attenuate signals in a quantum computing system (QCS). Similar to enhanced cryogenic system 410 of FIG. 4, the enhanced cryogenic system 510 shown in FIG. 5 may be an alternating current (AC) embodiment because it is directed towards an AC (e.g., a radiofrequency (RF)) input signal 412. However, the embodiment shown in FIG. 5 is not so limited and may be a direct current (DC) embodiment, because it alternatively may be directed towards a DC input signal 512. The enhanced cryogenic system 510 of FIG. 5 may be considered a combination of the enhanced cryogenic system 210 of FIG. 2 and the enhanced cryogenic system 310 of FIG. 3, where the signal reflector element of cryogenic system 210 (i.e., the directional coupler 242) has been replaced with the signal reflector element of cryogenic system 310 (i.e., the resistor element 342).

Similar to cryogenic system 210 and cryogenic system 310, the enhanced cryogenic system 510 includes at least three stages: a room temperature (RT) stage 220, a cold stage 240, and an ultra-cold stage 260. The RT stage 220 may be operated at approximately 300 kelvins and may be interchangeably referred to as an initial stage of the cryogenic system 210. The cold stage 240 may be operated at approximately 3 kelvins and may be interchangeably referred to as an intermediate stage of the cryogenic system 210. The ultra-cold stage 260 may be operated at approximately 220 millikelvins and may be interchangeably referred to as a final stage of the cryogenic system 210. The ultra-cold stage 260 may house a set of quantum devices 262. The set of quantum devices 262 may include a set of qubits, a set of quantum logic gates, a set of qubit couplers (e.g., employable as quantum gates), and the like. For instance, the set of quantum devices may include the multiple qubits 120, the two-dimensional grid 122, and/or the qubit coupler 124 of FIG. 1B.

The enhanced cryogenic system 510 may further include a first signal line 514 (e.g., a control signal line), a second signal line 524, and the ground line 216 of FIG. 2. As shown in FIG. 5, the first signal line 514 may run from the RT stage 220, into the cold stage 240, and return back to the RT stage 220. As also shown in FIG. 5, the second signal line 524 may run from the ultra-cold stage 260, into the cold stage 240, and return to the ultra-cold stage 260. The first signal line 514 and the ground line 216 may be electrically coupled (in the RT stage 220) via a first resistor element 526 positioned in the RT stage 220. The second signal line 524 may be electrically coupled to ground (e.g., which may be but need not be the ground line 216) via a second resistor element 564 positioned in the ultra-cold stage 260. The first signal line 514 and the second signal line 524 may be electrically coupled in the cold stage 240 via a third resistor element 542. The ground line 216 and the second resistor element 564 may be electrically coupled to an electrical ground.

The resistance of the third resistor element 542 may be large enough that the third resistor element 542 may serve as a signal reflector element in the cold stage 240, as well as to electrically couple the first signal line 514 with the second signal line 524. That is, the third resistor element 542 may reflect a portion of the input signal 512 (e.g., the return signal 522) and transmit the remaining portion of the input signal (e.g., the output signal 518) to the second signal line 524. The third resistor element 542 may serve as a signal “splitter” element that splits the input signal 512 into a return signal 522 and an output signal 518, via a partial reflection of the input signal 512. The return signal 522 may be referred to as a reflected signal component (e.g., a first signal component) and the output signal 518 may be referred to as a transmitted signal component (e.g., a second signal component). Thus, via the partial reflection, the third resistor element 542 (e.g., a signal reflector element) is configured to split the input signal 512 into a reflected signal component (e.g., that is reflected by the signal reflector element) and a transmitted signal component (e.g., that is transmitted by the signal reflector element).

Via the splitting of the input signal 512 into the return signal 522 and the output signal 518, the third resistor element 542 may serve to attenuate the input signal 512. In some embodiments, the third resistor element 542 attenuates the input signal 512 by approximately 20 dBs. The attenuation accomplished via the third resistor element 542 is a “reflective” attenuation, rather than an absorptive attenuation, as shown in FIG. 1A. Accordingly, the signal attenuation accomplished in the cold stage 240 does not generate the heat in the cold stage 240, in contrast to the heat generation in the cold stage 40 of FIG. 1A. The return signal 522 is returned to the RT stage 220 via the first signal line 514, and the output signal 518 is provided to the ultra-cold stage 260 and one or more quantum devices of the set of quantum devices 262 via the second signal line 524.

The first resistor element 526 may act as a heat radiator and be referred to as a heat radiation resistor (e.g., Rₕₑₐₜ). The heat radiated by the first resistor element 526 is radiated to the RT stage 220. Because the RT stage 220 is approximately 300 kelvins, the RT stage 220 may serve as a heat sink for the heat radiated by the first resistor element 526. In some embodiments, the resistance of the first resistor element 526 may be approximately 50 ohms. The second resistor element 564 may “emit” the output signal 518 to the ultra-cold environment. Thus, the second resistor element 564 may be referred to as a signal an/or heat emitting resistor (e.g., Rₑₘᵢₜ). The second resistor element 564 may serve to thermalize the output signal 518 and/or the portion of the second signal line 524 that is in the ultra-cold stage 260. Because the output signal 518 has been significantly attenuated, the amount of heat deposited in the ultra-cold stage 260 has been significantly attenuated. In some embodiments, the resistance of the second resistor element 564 may be approximately 50 ohms.

In reference to FIG. 5, the cold stage 240 may include a first cryogenic chamber and the ultra-cold stage 260 may include a second cryogenic chamber. Thus, one or more quantum devices (e.g., a qubit, a qubit coupler, a quantum logic gate, or the like) of the set of quantum devices 262 may be positioned within the second cryogenic chamber. In at least one embodiment, the second cryogenic chamber may be nested in the first cryogenic chamber. The RT stage 220 may, or may not, include a third cryogenic chamber. That is, the RT stage 220 may be outside any cryogenic chamber. The RT stage may include an external environment that is external to each of the first cryogenic chamber and the second cryogenic chamber. A signal reflector element (e.g., the third resistor element 542) is positioned within the first cryogenic chamber. The signal reflector element is configured to split the input signal 512 into a first signal component (e.g., the return signal 522) and a second signal component (e.g., the output signal 518) via a partial reflection of the input signal 512. The partial reflection of the input signal 512 causes the first signal component of the input signal 212 to be reflected by the signal reflector element and the second signal component of the input signal 512 to be transmitted by the signal reflector element. The partial reflection of the input signal 512 causes an attenuation of the input signal 512 such that the second signal component (e.g., the output signal 518) is an attenuated signal of the input signal 512. The attenuation of the input signal 512 may be approximately a 20 decibel (dB) attenuation.

The first signal line 514 may be configured to provide the input signal 512 from an external environment (e.g., the RT stage 220) to the signal reflector element. As shown in FIG. 5, the input signal 512 may originate in the external environment. The first signal line 514 is further configured to provide the reflected first signal component from the signal reflector element to the external environment. The second signal line 524 is configured to provide the transmitted second signal component from the signal reflector element to the quantum device positioned within the second cryogenic chamber. The signal reflector element electrically couples the first signal line 514 to the second signal line 524 such that the second signal component transmitted by the signal reflector element is transmitted to the second signal line 524 via the signal reflector element.

The ground line 216 may pass through the external environment, the first cryogenic chamber, and the second cryogenic chamber. As shown in FIG. 5, the ground line 216 may be electrically coupled to an electrical ground. A resistor element (e.g., the first resistor element 526) may be positioned in the external environment. The first resistor element 526 couples the first signal line 214 to the electrical ground such that heat associated with energy of the first signal component (e.g., the return signal 522) is dissipated to the external environment. Another resistor element (e.g., the second resistor element 564) may be positioned in the second cryogenic chamber. The second resistor element 564 couples the second signal line 524 to the electrical ground such that the second signal component (e.g., the output signal 518) is at least partially thermalized in the second cryogenic chamber.

The first signal line 514 may include a first portion that transmits the input signal 512 from the external environment to the signal reflector element. The first signal line 514 may additionally include a second portion that transmits the first signal component (e.g., the return signal 522) from the signal reflector element to the external environment. The first portion and the second portion of the first signal line 514 may be disjoint portions such that the input signal 512 and the first signal component are transmitted by disjoint portions of the first signal line 514.

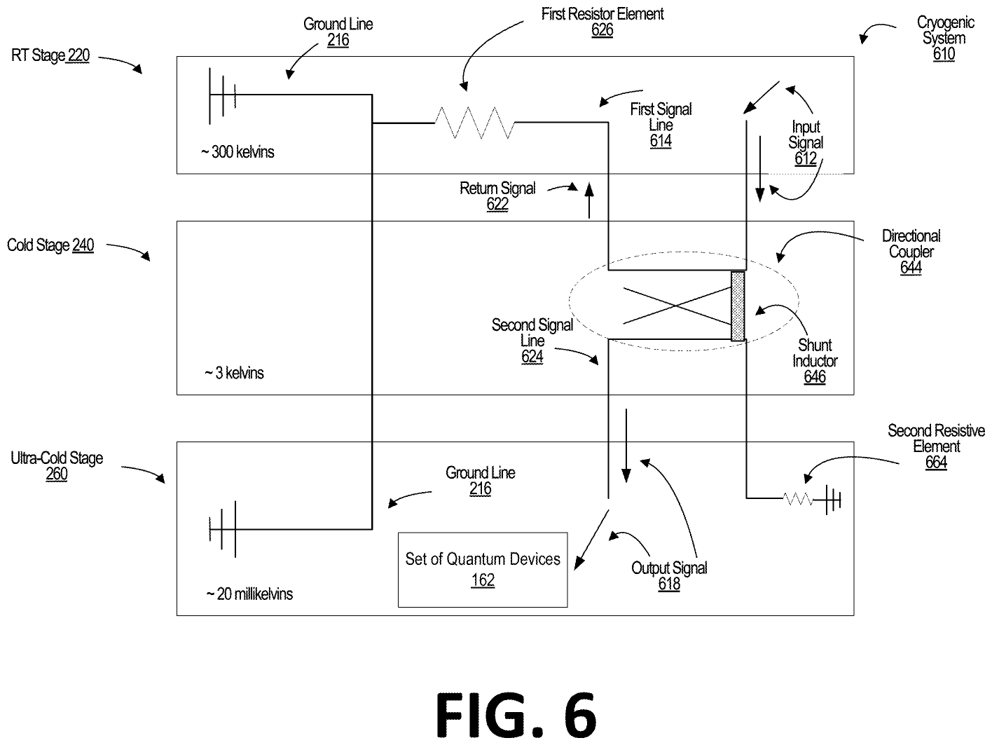

FIG. 6 provides a schematic view of yet another enhanced multi-stage cryogenic system 610 and an enhanced architecture that is employable to thermalize the signal lines and attenuate signals in a quantum computing system (QCS). The embodiment shown in FIG. 2 may be an alternating current (AC) embodiment because it is directed towards an AC (e.g., a radiofrequency (RF)) input signal 212. The enhanced cryogenic system 610 of FIG. 6 may be similar to the enhanced cryogenic system 210 of FIG. 2, with the addition of a shunt inductor to include with the signal reflector element of cryogenic system 210.

The enhanced cryogenic system 610 includes at least three stages: a room temperature (RT) stage 220, a cold stage 240, and an ultra-cold stage 260. The RT stage 220 may be operated at approximately 300 kelvins and may be interchangeably referred to as an initial stage of the cryogenic system 210. The cold stage 240 may be operated at approximately 3 kelvins and may be interchangeably referred to as an intermediate stage of the cryogenic system 210. The ultra-cold stage 260 may be operated at approximately 220 millikelvins and may be interchangeably referred to as a final stage of the cryogenic system 210. The ultra-cold stage 260 may house a set of quantum devices 262. The set of quantum devices 262 may include a set of qubits, a set of quantum logic gates, a set of qubit couplers (e.g., employable as quantum gates), and the like. For instance, the set of quantum devices may include the multiple qubits 120, the two-dimensional grid 122, and/or the qubit coupler 124 of FIG. 1B.

The enhanced cryogenic system 610 may further include a first signal line 614 (e.g., a control signal line), a second signal line 624, and the ground line 216 of FIG. 2. As shown in FIG. 2, the first signal line 214 may run from the RT stage 220, into the cold stage 240, and return back to the RT stage 220. As also shown in FIG. 6, the second signal line 624 may run from the ultra-cold stage 260, into the cold stage 240, and return to the ultra-cold stage 260. The first signal line 614 and the ground line 616 may be electrically coupled (in the RT stage 220) via a first resistor element 626 positioned in the RT stage 220. The second signal line 624 may be electrically coupled to ground (e.g., which may be but need not be the ground line 216) via a second resistor element 664 positioned in the ultra-cold stage 260. The first signal line 614 and the second signal line 624 may be electrically coupled in the cold stage 240 via a directional coupler 642 and the shunt inductor 646. The ground line 216 and the second resistor element 264 may be electrically coupled to an electrical ground.

The combination of the directional coupler 642 and the shunt inductor 644 may serve as a signal reflector element in the cold stage 240, as well as to electrically couple the first signal line 214 with the second signal line 224. That is, the combination of the directional coupler 642 and the shunt inductor 644 may reflect a portion of the input signal 612 (e.g., the return signal 622) and transmit the remaining portion of the input signal (e.g., output signal 618) to the second signal line 624. The combination of the directional coupler 642 and the shunt inductor 644 may serve as a signal “splitter” element that splits the input signal 612 into a return signal 622 and an output signal 618, via a partial reflection of the input signal 612. The return signal 622 may be referred to as a reflected signal component (e.g., a first signal component) and the output signal 618 may be referred to as a transmitted signal component (e.g., a second signal component). Thus, via the partial reflection, the combination of the directional coupler 642 and the shunt inductor 644 (e.g., a signal reflector element) is configured to split the input signal 612 into a reflected signal component (e.g., that is reflected by the signal reflector element) and a transmitted signal component (e.g., that is transmitted by the signal reflector element). The shunt inductor 646 may serve as a low pass filter for the transmitted output signal 618.

Via the splitting of the input signal 612 into the return signal 622 and the output signal 618, the combination of the directional coupler 642 and the shunt inductor 644 may serve to attenuate the input signal 612. In some embodiments, the combination of the directional coupler 642 and the shunt inductor 644 attenuates the input signal 612 by approximately 20 dBs. The attenuation accomplished via the combination of the directional coupler 642 and the shunt inductor 644 is a “reflective” attenuation, rather than an absorptive attenuation, as shown in FIG. 1A. Accordingly, the signal attenuation accomplished in the cold stage 240 does not generate the heat in the cold stage 240, in contrast to the heat generation in the cold stage 40 of FIG. 1A. The return signal 622 is returned to the RT stage 220 via the first signal line 614, and the output signal 618 is provided to the ultra-cold stage 260 and one or more quantum devices of the set of quantum devices 262 via the second signal line 224.

The first resistor element 626 may act as a heat radiator and be referred to as a heat radiation resistor (e.g., Rₕₑₐₜ). The heat radiated by the first resistor element 626 is radiated to the RT stage 220. Because the RT stage 620 is approximately 300 kelvins, the RT stage 220 may serve as a heat sink for the heat radiated by the first resistor element 626. In some embodiments, the resistance of the first resistor element 626 may be approximately 50 ohms. The second resistor element 664 may “emit” the output signal 618 to the ultra-cold environment. Thus, the second resistor element 664 may be referred to as a signal an/or heat emitting resistor (e.g., Rₑₘᵢₜ). The second resistor element 664 may serve to thermalize the output signal 618 and/or the portion of the second signal line 624 that is in the ultra-cold stage 260. Because the output signal 618 has been significantly attenuated, the amount of heat deposited in the ultra-cold stage 260 has been significantly attenuated. In some embodiments, the resistance of the second resistor element 664 may be approximately 50 ohms.

In reference to FIG. 6, the cold stage 240 may include a first cryogenic chamber and the ultra-cold stage 260 may include a second cryogenic chamber. Thus, one or more quantum devices (e.g., a qubit, a qubit coupler, a quantum logic gate, or the like) of the set of quantum devices 262 may be positioned within the second cryogenic chamber. In at least one embodiment, the second cryogenic chamber may be nested in the first cryogenic chamber. The RT stage 220 may, or may not, include a third cryogenic chamber. That is, the RT stage 220 may be outside any cryogenic chamber. The RT stage may include an external environment that is external to each of the first cryogenic chamber and the second cryogenic chamber. A signal reflector element (e.g., the combination of the directional coupler 642 and the shunt inductor 644) is positioned within the first cryogenic chamber. The signal reflector element is configured to split the input signal 612 into a first signal component (e.g., the return signal 622) and a second signal component (e.g., the output signal 618) via a partial reflection of the input signal 612. The partial reflection of the input signal 612 causes the first signal component of the input signal 612 to be reflected by the signal reflector element and the second signal component of the input signal 612 to be transmitted by the signal reflector element. The partial reflection of the input signal 612 causes an attenuation of the input signal 612 such that the second signal component (e.g., the output signal 618) is an attenuated signal of the input signal 612. The attenuation of the input signal 612 may be approximately a 20 decibel (dB) attenuation. The input signal 212 may be a radiofrequency (RF) signal.

The first signal line 614 may be configured to provide the input signal 612 from an external environment (e.g., the RT stage 220) to the signal reflector element. As shown in FIG. 6, the input signal 612 may originate in the external environment. The first signal line 614 is further configured to provide the reflected first signal component from the signal reflector element to the external environment. The second signal line 624 is configured to provide the transmitted second signal component from the signal reflector element to the quantum device positioned within the second cryogenic chamber. The signal reflector element electrically couples the first signal line 614 to the second signal line 624 such that the second signal component transmitted by the signal reflector element is transmitted to the second signal line 624 via the signal reflector element.

The ground line 616 may pass through the external environment, the first cryogenic chamber, and the second cryogenic chamber. As shown in FIG. 6, the ground line 216 may be electrically coupled to an electrical ground. A resistor element (e.g., the first resistor element 626) may be positioned in the external environment. The first resistor element 226 couples the first signal line 614 to the electrical ground such that heat associated with energy of the first signal component (e.g., the return signal 622) is dissipated to the external environment. Another resistor element (e.g., the second resistor element 664) may be positioned in the second cryogenic chamber. The second resistor element 664 couples the second signal line 624 to the electrical ground such that the second signal component (e.g., the output signal 618) is at least partially thermalized in the second cryogenic chamber.

The first signal line 614 may include a first portion that transmits the input signal 612 from the external environment to the signal reflector element. The first signal line 614 may additionally include a second portion that transmits the first signal component (e.g., the return signal 622) from the signal reflector element to the external environment. The first portion and the second portion of the first signal line 614 may be disjoint portions such that the input signal 612 and the first signal component are transmitted by disjoint portions of the first signal line 614.

Implementations of the digital, classical, and/or quantum subject matter and the digital functional operations and quantum operations described in this specification can be implemented in digital electronic circuitry, suitable quantum circuitry or, more generally, quantum computational systems, in tangibly-implemented digital and/or quantum computer software or firmware, in digital and/or quantum computer hardware, including the structures disclosed in this specification and their structural equivalents, or in combinations of one or more of them. The term “quantum computing systems” may include, but is not limited to, quantum computers/computing systems, quantum information processing systems, quantum cryptography systems, or quantum simulators.

Implementations of the digital, classical, and/or quantum subject matter and the digital functional operations and quantum operations described in this specification can be implemented in digital electronic circuitry, suitable quantum circuitry or, more generally, quantum computational systems, in tangibly-implemented digital and/or quantum computer software or firmware, in digital and/or quantum computer hardware, including the structures disclosed in this specification and their structural equivalents, or in combinations of one or more of them. The term “quantum computing systems” may include, but is not limited to, quantum computers/computing systems, quantum information processing systems, quantum cryptography systems, or quantum simulators.

Implementations of the digital and/or quantum subject matter described in this specification can be implemented as one or more digital and/or quantum computer programs, i.e., one or more modules of digital and/or quantum computer program instructions encoded on a tangible non-transitory storage medium for execution by, or to control the operation of, data processing apparatus. The digital and/or quantum computer storage medium can be a machine-readable storage device, a machine-readable storage substrate, a random or serial access memory device, one or more qubits/qubit structures, or a combination of one or more of them. Alternatively or in addition, the program instructions can be encoded on an artificially-generated propagated signal that is capable of encoding digital and/or quantum information (e.g., a machine-generated electrical, optical, or electromagnetic signal) that is generated to encode digital and/or quantum information for transmission to suitable receiver apparatus for execution by a data processing apparatus.

The terms quantum information and quantum data refer to information or data that is carried by, held, or stored in quantum systems, where the smallest non-trivial system is a qubit, i.e., a system that defines the unit of quantum information. It is understood that the term “qubit” encompasses all quantum systems that may be suitably approximated as a two-level system in the corresponding context. Such quantum systems may include multi-level systems, e.g., with two or more levels. By way of example, such systems can include atoms, electrons, photons, ions or superconducting qubits. In many implementations the computational basis states are identified with the ground and first excited states, however it is understood that other setups where the computational states are identified with higher level excited states (e.g., qubits) are possible.

The term “data processing apparatus” refers to digital and/or quantum data processing hardware and encompasses all kinds of apparatus, devices, and machines for processing digital and/or quantum data, including by way of example a programmable digital processor, a programmable quantum processor, a digital computer, a quantum computer, or multiple digital and quantum processors or computers, and combinations thereof. The apparatus can also be, or further include, special purpose logic circuitry, e.g., an FPGA (field programmable gate array), or an ASIC (application-specific integrated circuit), or a quantum simulator, i.e., a quantum data processing apparatus that is designed to simulate or produce information about a specific quantum system. In particular, a quantum simulator is a special purpose quantum computer that does not have the capability to perform universal quantum computation. The apparatus can optionally include, in addition to hardware, code that creates an execution environment for digital and/or quantum computer programs, e.g., code that constitutes processor firmware, a protocol stack, a database management system, an operating system, or a combination of one or more of them.

A digital or classical computer program, which may also be referred to or described as a program, software, a software application, a module, a software module, a script, or code, can be written in any form of programming language, including compiled or interpreted languages, or declarative or procedural languages, and it can be deployed in any form, including as a stand-alone program or as a module, component, subroutine, or other unit suitable for use in a digital computing environment. A quantum computer program, which may also be referred to or described as a program, software, a software application, a module, a software module, a script, or code, can be written in any form of programming language, including compiled or interpreted languages, or declarative or procedural languages, and translated into a suitable quantum programming language, or can be written in a quantum programming language, e.g., QCL, Quipper, Cirq, etc.

A digital and/or quantum computer program may, but need not, correspond to a file in a file system. A program can be stored in a portion of a file that holds other programs or data, e.g., one or more scripts stored in a markup language document, in a single file dedicated to the program in question, or in multiple coordinated files, e.g., files that store one or more modules, sub-programs, or portions of code. A digital and/or quantum computer program can be deployed to be executed on one digital or one quantum computer or on multiple digital and/or quantum computers that are located at one site or distributed across multiple sites and interconnected by a digital and/or quantum data communication network. A quantum data communication network is understood to be a network that may transmit quantum data using quantum systems, e.g. qubits. Generally, a digital data communication network cannot transmit quantum data, however a quantum data communication network may transmit both quantum data and digital data.

The processes and logic flows described in this specification can be performed by one or more programmable digital and/or quantum computers, operating with one or more digital and/or quantum processors, as appropriate, executing one or more digital and/or quantum computer programs to perform functions by operating on input digital and quantum data and generating output. The processes and logic flows can also be performed by, and apparatus can also be implemented as, special purpose logic circuitry, e.g., an FPGA or an ASIC, or a quantum simulator, or by a combination of special purpose logic circuitry or quantum simulators and one or more programmed digital and/or quantum computers.

For a system of one or more digital and/or quantum computers or processors to be “configured to” or “operable to” perform particular operations or actions means that the system has installed on it software, firmware, hardware, or a combination of them that in operation cause the system to perform the operations or actions. For one or more digital and/or quantum computer programs to be configured to perform particular operations or actions means that the one or more programs include instructions that, when executed by digital and/or quantum data processing apparatus, cause the apparatus to perform the operations or actions. A quantum computer may receive instructions from a digital computer that, when executed by the quantum computing apparatus, cause the apparatus to perform the operations or actions.

Digital and/or quantum computers suitable for the execution of a digital and/or quantum computer program can be based on general or special purpose digital and/or quantum microprocessors or both, or any other kind of central digital and/or quantum processing unit. Generally, a central digital and/or quantum processing unit will receive instructions and digital and/or quantum data from a read-only memory, or a random access memory, or quantum systems suitable for transmitting quantum data, e.g. photons, or combinations thereof.

Some example elements of a digital and/or quantum computer are a central processing unit for performing or executing instructions and one or more memory devices for storing instructions and digital and/or quantum data. The central processing unit and the memory can be supplemented by, or incorporated in, special purpose logic circuitry or quantum simulators. Generally, a digital and/or quantum computer will also include, or be operatively coupled to receive digital and/or quantum data from or transfer digital and/or quantum data to, or both, one or more mass storage devices for storing digital and/or quantum data, e.g., magnetic, magneto-optical disks, or optical disks, or quantum systems suitable for storing quantum information. However, a digital and/or quantum computer need not have such devices.

Digital and/or quantum computer-readable media suitable for storing digital and/or quantum computer program instructions and digital and/or quantum data include all forms of non-volatile digital and/or quantum memory, media and memory devices, including by way of example semiconductor memory devices, e.g., EPROM, EEPROM, and flash memory devices; magnetic disks, e.g., internal hard disks or removable disks; magneto-optical disks; and CD-ROM and DVD-ROM disks; and quantum systems, e.g., trapped atoms or electrons. It is understood that quantum memories are devices that can store quantum data for a long time with high fidelity and efficiency, e.g., light-matter interfaces where light is used for transmission and matter for storing and preserving the quantum features of quantum data such as superposition or quantum coherence.

Control of the various systems described in this specification, or portions of them, can be implemented in a digital and/or quantum computer program product that includes instructions that are stored on one or more tangible, non-transitory machine-readable storage media, and that are executable on one or more digital and/or quantum processing devices. The systems described in this specification, or portions of them, can each be implemented as an apparatus, method, or electronic system that may include one or more digital and/or quantum processing devices and memory to store executable instructions to perform the operations described in this specification.

While this specification contains many specific implementation details, these should not be construed as limitations on the scope of what may be claimed, but rather as descriptions of features that may be specific to particular implementations. Certain features that are described in this specification in the context of separate implementations can also be implemented in combination in a single implementation. Conversely, various features that are described in the context of a single implementation can also be implemented in multiple implementations separately or in any suitable sub combination. Moreover, although features may be described above as acting in certain combinations and even initially claimed as such, one or more features from a claimed combination can in some cases be excised from the combination, and the claimed combination may be directed to a sub-combination or variation of a sub-combination.

Similarly, while operations are depicted in the drawings in a particular order, this should not be understood as requiring that such operations be performed in the particular order shown or in sequential order, or that all illustrated operations be performed, to achieve desirable results. In certain circumstances, multitasking and parallel processing may be advantageous. Moreover, the separation of various system modules and components in the implementations described above should not be understood as requiring such separation in all implementations, and it should be understood that the described program components and systems can generally be integrated together in a single software product or packaged into multiple software products.

Particular implementations of the subject matter have been described. Other implementations are within the scope of the following claims. For example, the actions recited in the claims can be performed in a different order and still achieve desirable results. As one example, the processes depicted in the accompanying figures do not necessarily require the particular order shown, or sequential order, to achieve desirable results. In some cases, multitasking and parallel processing may be advantageous.

What is claimed is:

1. A quantum computing system comprising:
a first cryogenic chamber;
a signal reflector element, positioned within the first cryogenic chamber, being configured to split an input signal into a first signal component and a second signal component via a partial reflection of the input signal that causes the first signal component of the input signal to be reflected by the signal reflector element and the second signal component of the input signal to be transmitted by the signal reflector element;
a second cryogenic chamber;
a quantum device positioned within the second cryogenic chamber;
a first signal line configured to provide the input signal from an external environment to the signal reflector element and to provide the reflected first signal component from the signal reflector element to the external environment, wherein the external environment is external to each of the first cryogenic chamber and the second cryogenic chamber; and
a second signal line configured to provide the transmitted second signal component from the signal reflector element to the quantum device positioned within the second cryogenic chamber, wherein the signal reflector element electrically couples the first signal line to the second signal line such that the second signal component transmitted by the signal reflector element is transmitted to the second signal line via the signal reflector element.

2. The quantum computing system of claim 1, wherein the signal reflector element includes a directional coupler and the input signal is an alternating current (AC) signal.

3. The quantum computing system of claim 1, wherein the first cryogenic chamber is included in an intermediate stage of a cryogenic system of the quantum computing system and is operated at a temperature of approximately 3 kelvins.

4. The quantum computing system of claim 1, wherein the second cryogenic chamber is included in an ultra-cold stage of a cryogenic system of the quantum computing system and is operated at a temperature of approximately 20 millikelvins or less.

5. The quantum computing system of claim 1, wherein the input signal originates in the external environment and the external environment is at approximately 300 kelvins or greater.

6. The quantum computing system of claim 1, further comprising:
a ground line passing through the external environment, the first cryogenic chamber, and the second cryogenic chamber, wherein the ground line is electrically coupled to an electrical ground.

7. The quantum computing system of claim 1, further comprising:
a resistor element positioned in the external environment that couples the first signal line to an electrical ground such that heat associated with energy of the first signal component is dissipated to the external environment.

8. The quantum computing system of claim 1, further comprising:
a resistor element positioned in the second cryogenic chamber that couples the second signal line to an electrical ground such that the second signal component is at least partially thermalized in the second cryogenic chamber.

9. The quantum computing system of claim 1, wherein the partial reflection of the input signal causes an attenuation of the input signal such that the second signal component is an attenuated signal of the input signal.

10. The quantum computing system of claim 1, wherein the attenuated signal is approximately a 20 decibel (dB) or greater attenuation relative to the input signal.

11. The quantum computing system of claim 1, wherein the signal reflector element includes a resistor element and the input signal is a direct current (DC) signal.

12. The quantum computing system of claim 1, wherein the signal reflector element includes a circulator element and the input signal is an alternating current (AC) signal.

13. The quantum computing system of claim 1, wherein the first signal line includes a first portion that is configured to transmit the input signal from the external environment to the signal reflector element and a second portion, which is disjoint from the first portion, that is configured to transmit the first signal component from the signal reflector element to the external environment such that the input signal and the first signal component are transmitted by disjoint portions of the first signal line.

14. The quantum computing system of claim 13, wherein the signal reflector element includes a resistor element.

15. The quantum computing system of claim 13, wherein the signal reflector element includes a directional coupler and the input signal is a radiofrequency (RF) signal.

16. The quantum computing system of claim 15, wherein the signal reflector element further includes a shunt inductor that acts as a low pass filter for the RF signal.

17. The quantum computing system of claim 1, wherein the first signal line includes a common portion that is configured to transmit the input signal from the external environment to the signal reflector element and transmits the first signal component from the signal reflector element to the external environment such that the input signal and the first signal component are both transmitted by the common portion of the first signal line.

18. The quantum computing system of claim 1, wherein the quantum device is a qubit.

19. A cryogenic system comprising:
a first cryogenic chamber;
a signal reflector element, positioned within the first cryogenic chamber, being configured to split an input signal into a first signal component and a second signal component via a partial reflection of the input signal that causes the first signal component of the input signal to be reflected by the signal reflector element and the second signal component of the input signal to be transmitted by the signal reflector element;
a second cryogenic chamber;
a first signal line configured to provide the input signal from an external environment to the signal reflector element and to provide the reflected first signal component from the signal reflector element to the external environment, wherein the external environment is external to each of the first cryogenic chamber and the second cryogenic chamber; and
a second signal line configured to provide the transmitted second signal component from the signal reflector element to the second cryogenic chamber, wherein the signal reflector element electrically couples the first signal line to the second signal line such that the second signal component transmitted by the signal reflector element is transmitted to the second signal line via the signal reflector element. 20 A computing system comprising:
a signal reflector element being configured to split an input signal into a first signal component and a second signal component via a partial reflection of the input signal that causes the first signal component of the input signal to be reflected by the signal reflector element and the second signal component of the input signal to be transmitted by the signal reflector element;
an information-encoding device;
a first signal line configured to provide the input signal to the signal reflector element and to provide the reflected first signal component from the signal reflector element to a room temperature (RT) environment; and
a second signal line configured to provide the transmitted second signal component from the signal reflector element to the information-encoding device.
